(19) United States
(12) Patent Application Publication
(10) Pub. No.: US 2026/0331198 A1
(43) Pub. Date: Oct. 22, 2026

(54) PROCESS FOR TESTING THROUGH-SILICON VIA CONNECTIONS IN MEMORY DEVICES

(71) Applicant: Micron Technology, Inc., Boise, ID (US)

(72) Inventors: Yasir Husain, Boise, ID (US); Shailesh Kayambady Sathyanarayana Bhat, Folsom, CA (US); Bokuba Nwengela, El Dorado Hills, CA (US); Raymond Chang, Boise, ID (US); Raghukiran Sreeramaneni, McKinney, TX (US); Nevil N. Gajera, Parker, TX (US)

(21) Appl. No.: 19/468,049

(22) Filed: Feb. 3, 2026

Related U.S. Application Data
(60) Provisional application No. 63/758,696, filed on Feb. 14, 2025.

(51) Int. Cl. G11C 29/12

(52) U.S. Cl. CPC G11C 29/1201

(57) ABSTRACT

Systems, apparatuses, and methods related to testing through-silicon via connections in memory devices are described herein. One method includes transmitting data from a transmitter of one memory die of a plurality of memory dies to a receiver of another memory die of the plurality of memory dies, wherein the plurality of memory dies are stacked, selectively enabling a plurality of switches coupled to a respective set of TSVs within each memory die to establish a data path using a first portion of a plurality of sets of TSVs and through intermediate memory dies of the plurality of memory dies within the stack, wherein the established data path includes a portion of the plurality of memory dies within the stack, and enabling the first portion of the plurality of sets of TSVs for a test using data received at the another memory die and transferred through the data path.

### PRIORITY INFORMATION

This Application claims the benefits of U.S. Provisional Application Number 63/758,696, filed on Feb. 14, 2025, the contents of which are incorporated herein by reference.

### TECHNICAL FIELD

The present disclosure relates generally to semiconductor memory and methods, and more particularly, to apparatuses, systems, and methods for testing through-silicon via connections in memory devices

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), high bandwidth memory (HBM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices within a memory sub-system may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices within the memory sub-system.

As technology advances, memory systems are becoming faster, more efficient, and more compact to meet marked demands. With these advancements comes challenges regarding system and device maintenance, as well as failure detectability for longevity.

### BRIEF DESCRIPTION OF THE DRAWINGS

FIG. 1 is a block diagram of a computing system in accordance with a number of embodiments of the present disclosure.

FIG. 2 illustrates an example of a memory device including through-silicon via connections in accordance with a number of embodiments of the present disclosure.

FIG. 3 illustrates an example apparatus including through-silicon via connections in accordance with a number of embodiments of the present disclosure.

FIG. 4 illustrates an example apparatus including through-silicon via connections in accordance with a number of embodiments of the present disclosure.

FIG. 5 illustrates an example apparatus including through-silicon via connections in accordance with a number of embodiments of the present disclosure.

FIG. 6 illustrates a method of testing through-silicon via connections in memory devices in accordance with a number of embodiments of the present disclosure.

### DETAILED DESCRIPTION

Systems, apparatuses, and methods related to testing through-silicon via connections in memory devices are described herein. One method includes transmitting data from a transmitter of one memory die of a plurality of memory dies to a receiver of another memory die of the plurality of memory dies, wherein the plurality of memory dies are in a stacked configuration, selectively enabling a plurality of switches coupled to a respective set of TSVs within each memory die to establish a data path using a first portion of a plurality of sets of TSVs and through intermediate memory dies of the plurality of memory dies within the stack, wherein the established data path includes a portion of the plurality of memory dies within the stack, and enabling the first portion of the plurality of sets of TSVs for a test using data received at the another memory die and transferred through the data path.

Signaling may be routed through stacked memory dice via through-silicon vias (TSVs) to each memory die and a control die (e.g., for a hybrid memory cube). TSV connections may be utilized in high-bandwidth memory (HBM) cubes to facilitate communication through each memory die within the stacked memory. In previous approaches, an HBM cube must be packaged to a final stack height (e.g., 16H stack, 16 DRAM memory dies), along with a base die (e.g., control die) before the TSV connections can be tested. However, as HBM stacks continue to scale to 16H and beyond, such approaches can yield significant loss if a TSV failure can only be caught after the entire HBM stack has been packaged.

Aspects of the present disclosure address the above and other challenges for memory systems including stacked memory dice (e.g., HBM cube). For example, TSV connections may be tested for smaller DRAM stack heights (e.g., 4H) before reaching a final stack height. In some embodiments, the TSV connections can be tested without a base die.

HBM stacks of four memory dice and beyond may utilize 4-Spiral Data TSV connections for communicating among core memory dice. Each core die can include a transmitter and receiver for facilitating communication via the TSVs. The transmitter and receiver may be coupled to one of the 4-Spiral TSVs on each core die, which may be referred to as an active TSV. The remaining TSVs (e.g., passthrough TSVs) may be coupled to the active TSV via a number of switches. By enabling a combination of switches, a data path via the TSVs may be altered. Test data may be loaded via a transmitter of one core die and captured via a receiver of another core die. The captured data may be compared to the expected data to determine whether a TSV failure is present within a plurality of core dice.

The embodiments of the present disclosure provide improved failure detectability for TSV connections through testing of smaller intermediate DRAM stack heights (e.g., 4H). This allows for improved yield through TSV failure detection before final packaging of an HBM stack.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

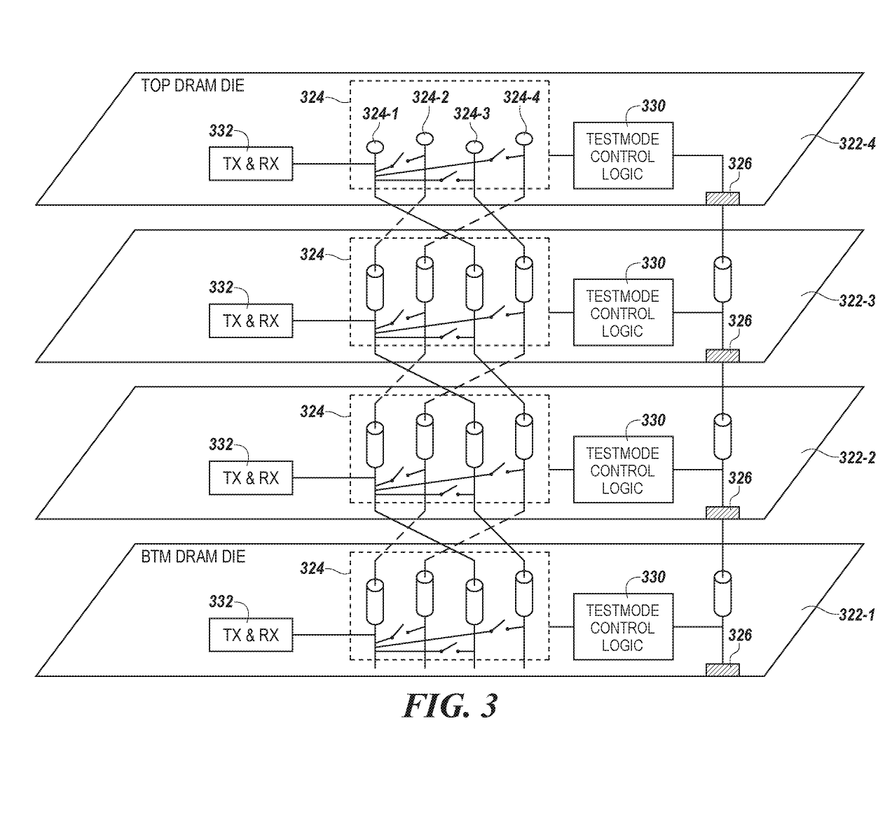

The figures herein follow a numbering convention in which the first digit or digits correspond to the drawing figure number and the remaining digits identify an element or component in the drawing. Similar elements or components between different figures may be identified by the use of similar digits. For example, 222 may reference element “22” in FIG. 2, and a similar element may be referenced as 322 in FIG. 3.

Analogous elements within a Figure may be referenced with a hyphen and extra numeral or letter. See, for example, elements 322-1, …, 322-4 in FIG. 3. Such analogous elements may be generally referenced without the hyphen and extra numeral or letter. For example, elements 322-1, …, 322-4 may be collectively referenced as 322. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

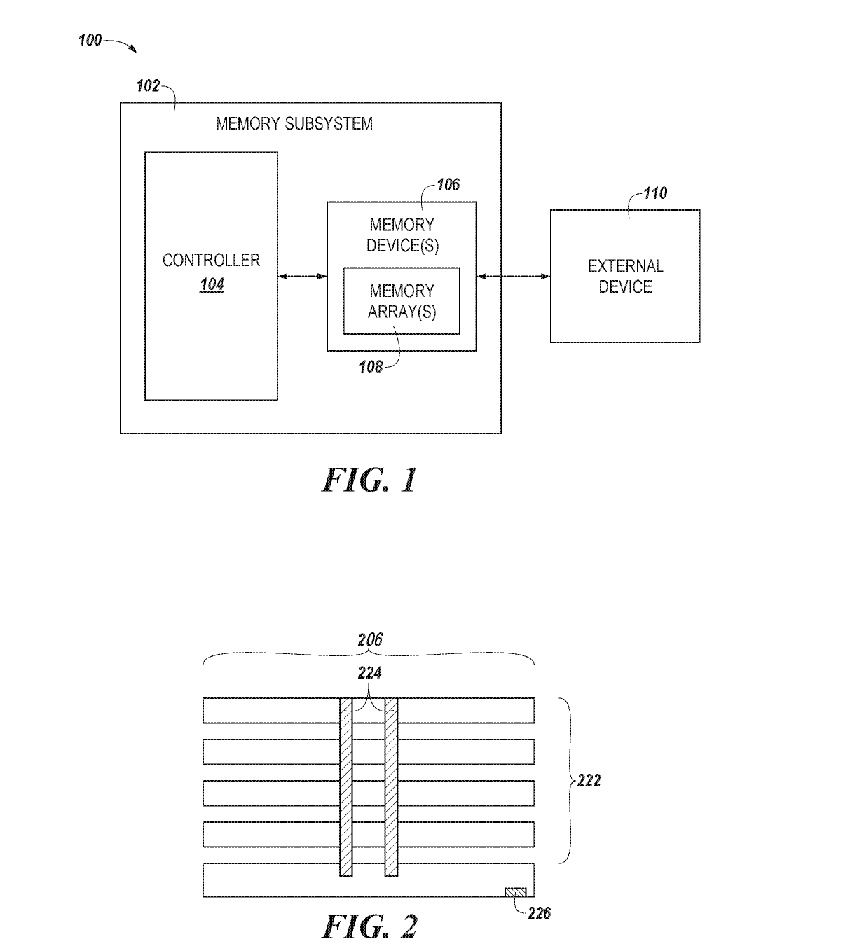

FIG. 1 is a block diagram of a computing system 100 in accordance with a number of embodiments of the present disclosure. The computing system 100 includes a memory subsystem 102, a controller 104, and memory device(s) 106 which might also be separately considered an “apparatus.” Memory device(s) 106 may include memory array(s) 108. Memory devices(s) 106 may also be coupled to an external device 110.

The memory subsystem 102 may be coupled to a host (not illustrated) via an interface coupled to the controller 104. A host may be coupled to the controller 104 via any type of communication path, bus, or the like that allows for information to be transferred between a host and the controller 104.

A host can be a host system such as a personal laptop computer, a desktop computer, a digital camera, a smart phone, a memory card reader, and/or internet-of-thing enabled device, among various other types of hosts, and can include a memory access device (e.g., a processor and/or processing device). One of ordinary skill in the art will appreciate that “a processor” can intend one or more processors, such as a parallel processing system, a number of coprocessors, etc.

The controller 104 can control performance of a memory operation for an access command received from a host. The memory operation can be a memory operation to read data (in response to a read request from the host) from or an operation to write data (in response to a write request from the host) to one or more memory device(s) 106. The controller 104 can control operations of the memory subsystem 102.

The memory device(s) 106 can provide main memory for the computing system 100 or could be used as additional memory or storage throughout the computing system 100. The memory device(s) 106 can be various/different types of memory devices. For instance, the memory device can include RAM, ROM, DRAM, SDRAM, PCRAM, RRAM, and flash memory, among others. In embodiments in which the memory device 106 includes persistent or non-volatile memory, the memory device 106 can be flash memory devices such as NAND or NOR flash memory devices. Embodiments are not so limited, however, and the memory device 106 can include other non-volatile memory devices such as non-volatile random-access memory devices (e.g., non-volatile RAM (NVRAM), ReRAM, ferroelectric RAM (FeRAM), MRAM, PCRAM), “emerging” memory devices such as a ferroelectric RAM device that includes ferroelectric capacitors that can exhibit hysteresis characteristics, a memory device with resistive, phase-change, or similar memory cells, etc., or combinations thereof.

As an example, a FeRAM device can include ferroelectric capacitors and can perform bit storage based on an amount of voltage or charge applied thereto. In such examples, relatively small and relatively large voltages allow the ferroelectric RAM device to exhibit characteristics similar to normal dielectric materials (e.g., dielectric materials that have a relatively high dielectric constant) but at various voltages between such relatively small and large voltages the ferroelectric RAM device can exhibit a polarization reversal that yields non-linear dielectric behavior.

As another example, an array of non-volatile memory cells, such as resistive, phase-change, or similar memory cells, can perform bit storage based on a change of bulk resistance, in conjunction with a stackable cross-gridded data access array. Additionally, in contrast to many flash-based memories, the non-volatile memory can perform a write in-place operation, where a non-volatile memory cell can be programmed without the non-volatile memory cell being previously erased.

One example of memory device(s) 106 is dynamic random access memory (DRAM) operated according to a protocol such as low-power double data rate (LPDDRx), which may be referred to herein as LPDDRx DRAM devices, LPDDRx memory, etc. The “x” in LPDDRx refers to any of a number of generations of the protocol (e.g., LPDDR5). In at least one embodiment, at least one of the memory device(s) 106 is operated as an LPDDRx DRAM device with low-power features enabled and at least one of the memory device(s) 106 is operated an LPDDRx DRAM device with at least one low-power feature disabled. In some embodiments, although the memory device(s) 106 are LPDDRx memory devices, the memory device(s) 106 do not include circuitry configured to provide low-power functionality for the memory device(s) 106 such as a dynamic voltage frequency scaling core (DVFSC), a sub-threshold current reduce circuit (SCRC), or other low-power functionality providing circuitry. Providing the LPDDRx memory device(s) 106 without such circuitry can advantageously reduce the cost, size, and/or complexity of the LPDDRx memory device(s) 106. By way of example, an LPDDRx memory device 106 with reduced low-power functionality providing circuitry can be used for applications other than mobile applications (e.g., if the memory is not intended to be used in a mobile application, some or all low-power functionality may be sacrificed for a reduction in the cost of producing the memory).

The memory device(s) 106 can each comprise a number of memory dice (e.g., memory dice 222 illustrated in FIG. 2). These memory dice can be linked memory dice. In some embodiments, these linked memory dice can be “stacked” memory dice. For example, multiple stacked memory dies may form a High Bandwidth Memory (HBM) cube, where each memory dice is connected via through-silicon vias (TSVs) (e.g., 224 of FIG. 2). A stack, as used herein, may refer to an individual DRAM die within the vertical structure of an HBM cube, for example. Each die includes its own memory array(s) 108. For example, each die within a stack may contain multiple memory arrays 108 organized into banks for storing data.

The memory device(s) 106 may be coupled to an external device 110. The external device 110 may be a testing device (e.g., tester) that may be coupled to a probe pad (e.g., set of test connectors) of a memory device in order to facilitate direct communication between the external device 110 and the memory device(s) 106. For example, the external device 110 may send signals to and/or receive signals from the memory device(s) 106. The external device 110 may be used to test the memory device(s) 106 before the memory dies (e.g., core dies) within the memory device 106 are mounted on a base die.

As used herein, the term “base die” refers to the foundational layer in a stacked memory system, serving as the interface between the stacked memory dice and external components. For example, the base die can include control circuitry, such as memory controllers or logic for managing data flow, power distribution, and communication within the memory stack and with external devices. As used herein, the term “core die” refers to an individual memory die (that is not a base die) within a stacked memory system, responsible for storing and processing data. Core dies can work collaboratively with other core dies in the stack to achieve high memory density and bandwidth, and they are interconnected via through-silicon vias (TSVs) for seamless communication within the memory system. The data can be communicated between the core dies and the external devices using the base die.

The external device 110 may be configured to provide one or more test instructions to the memory device(s) for performing a test of the TSV connections within the memory device(s) 106. A test may be enabled (e.g., performed) on the memory device(s) 106 based on the test instructions using testing circuitry (e.g., testmode control logic 330 illustrated in FIG. 3). The test instructions may correspond to one or more tests performed on the memory device(s) 106. The test may include loading data into one or more memory device(s) 106 as part of a write operation, retrieving the stored data as part of a read operation, and comparing the written data to the read data.

FIG. 2 illustrates an example of a memory device including through-silicon via connections in accordance with a number of embodiments of the present disclosure. The memory device 206 may be any one of memory device(s) 106 described in connection with FIG. 1.

Memory device 206 can include an HBM device, for example. The memory device may include one or more memory dice 222 (e.g., core dice). In some embodiments, the memory device 206 may include any number of memory dice 222 (e.g., there may be 2, 4, 8, or other quantities of memory dice 222). The memory dice may be in a stacked configuration, as illustrated in FIG. 2. The memory dice may be connected via one or more through-silicon vias (TSVs) 224. While FIG. 2 illustrates two separate TSVs 224, embodiments are not limited to a particular quantity of TSVs the memory device 206 can include.

FIG. 2 illustrates memory dice 222; however, embodiments are not so limited to a particular quantity of memory dice that can be linked (e.g., coupled) together in a similar manner illustrated in FIG. 2. Each memory die (e.g., among memory dice 222) is not illustrated in its entirety in FIG. 2 and can further include other portions that are not illustrated in FIG. 2. For example, each memory die among memory dice 222 can include an array of memory cells where data externally received can be written to or data can be sent from. As illustrated in FIG. 2, memory dice 222 that are linked together can be “stacked” (e.g., stacked in a vertical manner).

The TSVs 224 may be vertical channels that extend through each memory die among the memory dice 222. The TSVs 224 may provide a direct pathway between the top and bottom memory die. Additionally, TSVs 224 may provide a communication pathway through each memory die of memory device 206 such that signals and data may be transmitted from one memory die to another.

Each memory die may include a probe pad 226 that may provide a direct interface between the memory dice 222 and an external device (e.g., external device 110 illustrated in FIG. 1). Although a probe pad is only illustrated on the bottom memory die of FIG. 2, a probe pad may be included on each memory die within the memory device 206 (as further illustrated in FIG. 3, for example) for interfacing with external devices.

FIG. 3 illustrates an example apparatus including through-silicon via connections in accordance with a number of embodiments of the present disclosure. The memory dice 322 illustrated in FIG. 3 may be any one of memory dice 222 described in connection with FIG. 2.

As illustrated in FIG. 3, memory die 322-1, 322-2, 322-3, 322-4, which may collectively be referred to as memory dice 322 (or individually be referred to as memory die 322), are in a stacked configuration with memory die 322-1 depicted as the bottom memory die (e.g., “BTM DRAM DIE” shown in FIG. 3) and memory die 322-4 depicted as the top memory die (e.g., “TOP DRAM DIE” shown in FIG. 3). Memory die 322-1, …, 322-4 may be stacked in a high-bandwidth memory configuration where the memory dice 322 are grouped in stacks of four. Although only four memory dice are illustrated, embodiments are not limited to a particular number or configuration and more or fewer memory dice may be included in particular embodiments.

A memory device may include a plurality of memory dies in a stacked configuration, wherein each memory die within the stack comprises a plurality of sets of through-silicon vias (TSVs) configured to transfer data from one memory die to another memory die, a test mode control logic unit configured to initiate a test of a respective set of the plurality of sets of TSVs by transferring the data from a transmitter of the one memory die to a receiver of the another memory die, a plurality of switches coupled to the respective set of the plurality of sets of TSVs and configured to establish a data path using a first portion of the plurality of sets of TSVs, and a probe pad configured to provide the transferred data to an external test circuit to determine if the test was successful.

Each memory die 322-1, …, 322-4 may include transmitter and receiver circuitry 332 (e.g., “TX & RX” shown in FIG. 3), TSVs 324, testmode control logic circuitry 330, and a probe pad 326. For example, as illustrated in FIG. 3, each memory die 322 includes a set of four TSVs (e.g., TSVs 324-1, 324-2, 324-3, and 324-4). More particularly, the memory die 322-1 includes four TSVs 324-1, …, 324-4; the memory die 322-2 includes four TSVs 324-1 (e.g., far left TSV within the memory die 322-2 as shown in FIG. 3), …, 324-4 (e.g., far right TSV within the memory die 322-2 as shown in FIG. 3); the memory die 322-3 includes four TSVs 324-1 (e.g., far left TSV within the memory die 322-3 as shown in FIG. 3), …, 324-4 (e.g., far right TSV within the memory die 322-3 as shown in FIG. 3); and the memory die 322-4 includes four TSVs 324-1 (e.g., far left TSV within the memory die 322-4 as shown in FIG. 3), …, 324-4 (e.g., far right TSV within the memory die 322-4 as shown in FIG. 3). Although not explicitly depicted in FIG. 3, each memory die 322 includes a set of four TSVs 324. These TSVs can be electrically connected to other components and circuitry within the memory die 322, such as interfaces and pads.

By enabling a combination of switches on each memory die 322-1, …, 322-4, a data path may be selectively altered in order to test out each TSV connection (e.g., enable each TSV connection for a test). As used herein, the term “TSV connection” refers to the electrical connection of at least two TSVs located on different memory dice, thereby forming a data path between the memory dice. For example, in the context of TSV testing, a TSV connection can be established among four TSVs, each located on memory dice 322-1, …, 322-4. For example, data may be driven using the transmitter from bottom memory die 322-1. By selectively enabling a combination of switches, a number of TSVs may be shorted to direct the data through a particular pathway of passthrough TSVs on each memory die. The data may be captured using the receiver of the top memory die 322-4, for example. The captured data may be read out using probe pad 326 and compared against expected data to determine whether a TSV fail (e.g., shorts and/or opens) is present. As used herein, the term “expected data” refers to a data pattern (e.g., a set of bits) that was initially sent (or at least intended to be sent) from the external device (e.g., the external device 110). For example, the test may be determined to be successful when the transferred data received by the other memory die matches the data transmitted from the one memory die.

As an example, memory dice may be stacked in groups of four and the TSV connections can be tested before stacking additional (e.g., four) memory dice onto the memory device. The TSVs 324 may be tested before a control die (e.g., base die) is added to the stack. The stack of memory dies may include Dynamic Random-Access Memory configured to form a High-bandwidth Memory (HBM) cube, for example. As illustrated in FIG. 3, the TSVs 324 are 4-Spiral TSVs. For example, each TSV among the TSVs 324 on memory die 322-1 may be connected to a neighboring TSV via an electrical connection. The communication between TSVs on a particular memory die may be controlled via a number of switches coupled to the TSVs 324. By enabling a combination of switches, the communication path between stacked memory dice may be established. In this way, TSV connections 324 may be tested before a final stack height is reached. As used herein, the term “final stack height” refers to the total height of a fully assembled memory stack, including all memory dice (e.g., 16 DRAM dies in a 16H stack) and a base die (e.g., control die), as packaged, for example, for final use in a high-bandwidth memory (HBM) cube or similar stacked memory system.

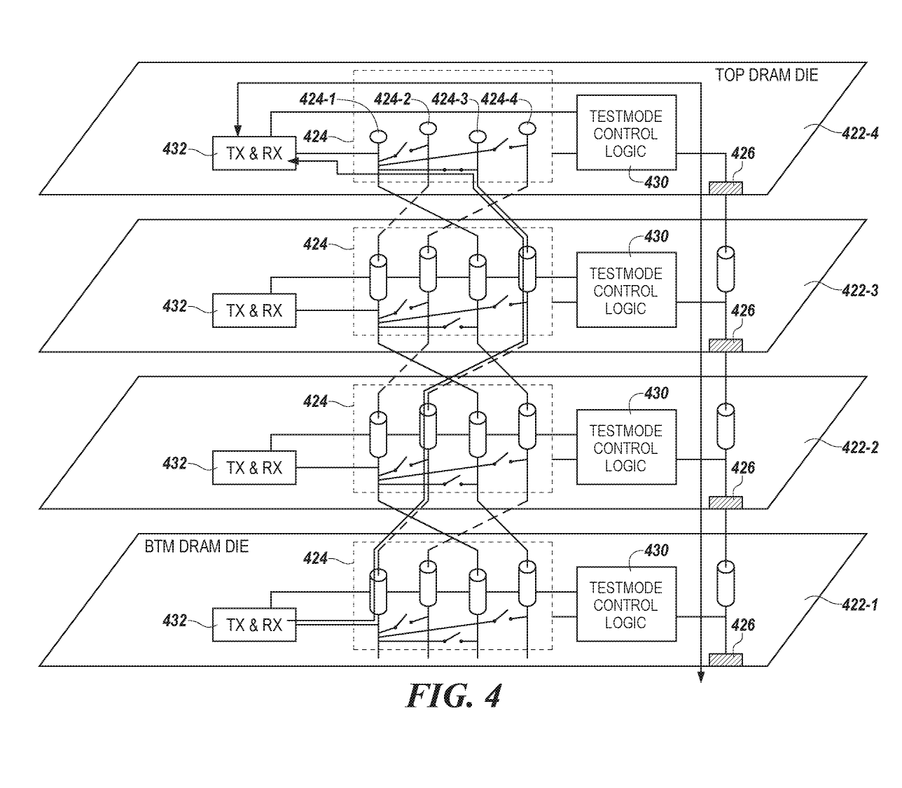

FIG. 4 illustrates an example apparatus including through-silicon via connections in accordance with a number of embodiments of the present disclosure. The memory dice 422-1, …, 422-4 illustrated in FIG. 4 may correspond to the memory dice 322-1, …, 322-4 described in connection with FIG. 3.

The apparatus illustrated in FIG. 4 may include a plurality of memory dies configured in a stack formation, a plurality of through-silicon vias (TSVs) configured to provide a communication pathway between the plurality of memory dies, a plurality of switches coupled to a respective set of TSVs among the plurality of TSVs and configured to control the communication pathway between the plurality of memory dies when activated by a test mode control logic unit, and a probe pad configured to provide data transmitted through the communication pathway to an external test circuit, wherein the external test circuit is configured to compare the transmitted data to an expected data, and determine whether the respective set of TSVs among the plurality of TSVs pass a test based on the comparison.

Memory die 422-1, 422-2, 422-3, 422-4 may be in a stacked configuration, coupled via through-silicon via connections 424. The TSVs 424 may be in groups of four (e.g., 424-1, 424-2, 424-3, 424-4) on each memory die. A first TSV (e.g., 424-1) among the four TSVs may be coupled to a transmitter and receiver 432 (e.g., “TX & RX” shown in FIG. 4) on each memory die. Testmode control logic may be coupled to the TSVs 424 and the transmitter and receiver 432. The testmode control logic may also be coupled to a probe pad 426 on each memory die for interfacing with an external device (not illustrated).

The transmitter and receiver circuitry 332 may be coupled to one of the TSVs on each memory die 322-1, …, 322-4. As illustrated in FIG. 3, 4-Spiral Data TSVs 324-1, 324-2, 324-3, 324-4 are utilized. As used herein, a 4-Spiral Data TSV consists of four spiral-shaped conductive pathways that run vertically through the silicon substrate of a memory die. The TSV coupled to the transmitter and receiver circuitry 332 may be referred to as the active TSV (e.g., 324-1

The testmode control logic 430 may control testing of the TSV connections. For example, test data may be loaded onto memory die 422-1 and driven via the transmitter 432 through the TSVs 424. The test data may be captured via the receiver 432 of memory die 422-4. The captured data may be read out using probe pad 426 and compared against expected data to determine whether a TSV fail is present. A TSV failure may be detected as shorts or opens, but other failure determinations may be made.

Each memory die may include testmode control logic 430. In this way, one memory die may be configured independently from the other memory dies. For example, the memory die 322-2 can be configured independently from the other memory dice 322-1, 322-3, and 322-4. The testmode control logic 430 may enable the respective transmitter and receiver 432 on a particular memory die. For example, testmode control logic 430 of memory die 422-1 may enable the transmitter 432 of memory die 422-1 and the testmode control logic 430 of memory die 422-4 may enable the receiver 432 to capture data transmitted through TSVs 424.

Each memory die 322-1, …, 322-4 may include switches to short the passthrough TSVs to the active TSV using testmode control logic 330. For example, three switches may be included on memory die 322-1 to connect each TSV (e.g., 324-1, …, 324-4) within the group of TSVs 324 of the memory die 322-1; three switches may be included on memory die 322-2 to connect each TSV (e.g., 324-1, …, 324-4) within the group of TSVs 324 of the memory die 322-2; three switches may be included on memory die 322-3 to connect each TSV (e.g., 324-1, …, 324-4) within the group of TSVs 324 of the memory die 322-3; and three switches may be included on memory die 322-4 to connect each TSV (e.g., 324-1, …, 324-4) within the group of TSVs 324 of the memory die 322-4.

A test of the TSV connections may be enabled (e.g., performed) by an external device, such as external device 110 of FIG. 1. Test data may be received by receiver 432 of memory die 422-1 and transmitted by transmitter 432 of memory die 422-1. The test data may be received in the form of signals originating from an external testing device. Test data may also be received in the form of test patterns loaded onto memory die 422-1 via probe pad 426. Each test performed may be unique such that a corresponding test pattern used may include random characteristics. In this way, each test may utilize a different test pattern for testing of the TSVs 424. By enabling different sets of TSVs through the activation of a combination of switches coupled to the different sets of TSVs, failures present within the enabled sets of TSVs may be detected.

The test illustrated in FIG. 4 corresponds to a test of TSV connections 424. For example, test data is loaded onto memory die 422-1 and driven via transmitter 432. The test data follows a particular data path through the TSVs 424 of memory dice 422. As illustrated in FIG. 4, the test data is transmitted through a first TSV (e.g., 424-1) on memory die 422-1. The test data is then routed to a passthrough TSV 424-2 of memory die 422-2 by enabling one or more switches on memory die 422-2, thereby enabling TSV 424-2. The test data is transmitted to another passthrough TSV 424-4 of memory die 422-3 before arriving at a final passthrough TSV 424-3 of memory die 422-4. As illustrated in FIG. 4, the passthrough TSV 424-3 of memory die 422-4 is configured to be (e.g., electrically) coupled to the receiver 432 of the memory die 422-4. The test data is captured via receiver 432 of memory die 422-4. The captured data is read out using probe pad 426 on memory die 422-1.

Various combinations of switches may be utilized such that a different data path is utilized to test remaining TSV connections 424. For example, test data may be loaded onto memory die 422-1 and transmitted through memory die 422-2, 422-3, and 422-4 such that the data is transmitted through the fourth TSV (e.g., 424-4) of each memory die. Alternatively, test data may be transmitted in a particular pattern such that the first TSV (e.g., 424-1) tested on memory die 422-1, the second TSV (e.g., 424-2) is tested on memory die 422-1, the third TSV (e.g., 424-3) on memory die 422-3, and the fourth TSV (e.g., 424-4) on memory die 422-4. Different combinations may be utilized to test the TSV connections of memory dice 422. Alternatively speaking, data paths can be formed on any combination of four TSVs (respectively on four memory dice 422-1, …, 422-4) such that multiple tests can be performed on various combinations. As used herein, a test can be performed on a singular data path or multiple data paths such that a first test is performed on a first data path and a second test is performed on a second data path.

As another example, test data may be loaded onto memory die 422-2 and captured via the receiver 432 of memory die 422-4. Alternatively, test data may be loaded onto memory die 422-4 and captured via the receiver of memory die 422-1. Embodiments are not limited to a particular data path or sequence. Various combinations of memory dice 422 may be utilized to test the TSV connections.

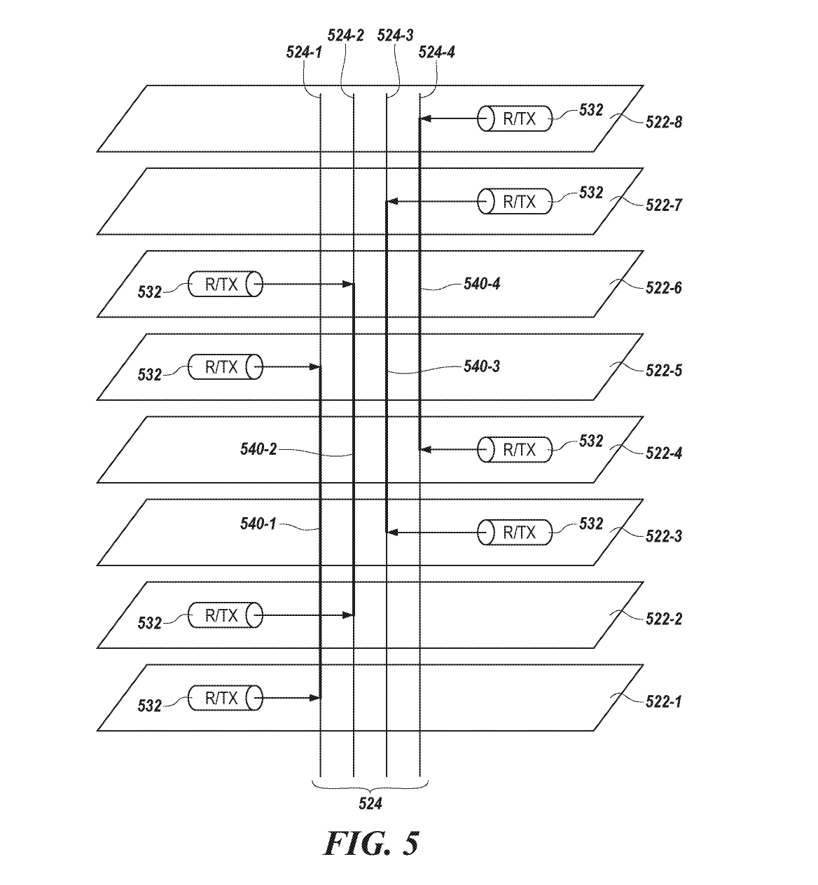

FIG. 5 illustrates an example apparatus including through-silicon via connections in accordance with a number of embodiments of the present disclosure. The memory dice 522 of FIG. 5 may correspond to memory dice 422 described in connection with FIG. 4. For example, memory dice 522 may include additional components and circuitry not illustrated so as to align with memory dice 422.

In the example apparatus illustrated in FIG. 5, a plurality of memory dice 522 are in a stacked configuration such that each memory die 522-1, 522-2, 522-3, 522-4, 522-5, 522-6, 522-7, 522-8 may communicate in sequence. Each memory die may be coupled to other memory dice via through-silicon vias (TSVs) 524. The TSVs 524 shown in FIG. 5 may be analogous to TSVs 424 of FIG. 4. TSVs 524 may be 4-Spiral TSVs such that four TSVs are utilized for facilitating communication among the memory dice 522.

Different data path can be established by selectively coupling receiver and transmitters 532 (e.g., “R/TX” shown in FIG. 5) in various manners. For example, a first data path can be established between memory dice 522-1 and 522-5 by coupling a transmitter 532 (or receiver 532) on memory die 522-1 and a receiver 532 (or transmitter 532) on memory die 522-5 to TSV 524-1 on memory dice 522-1 and 522-5; a second data path can be established between memory dice 522-2 and 522-6 by coupling a transmitter 532 (or receiver 532) on memory die 522-2 and a receiver 532 (or transmitter 532) on memory die 522-6 to TSV 524-1 on memory dice 522-2 and 522-6; a third data path can be established between memory dice 522-3 and 522-7 by coupling a transmitter 532 (or receiver 532) on memory die 522-3 and a receiver 532 (or transmitter 532) on memory die 522-7 to TSV 524-1 on memory dice 522-3 and 522-7; and a fourth data path can be established between memory dice 522-4 and 522-8 by coupling a transmitter 532 (or receiver 532) on memory die 522-4 and a receiver 532 (or transmitter 532) on memory die 522-8 to TSV 524-1 on memory dice 522-4 and 522-8.

As illustrated in FIG. 5, on the first data path, data may be driven through TSV 524-1 from transmitter 532 of memory die 522-1 and received by the receiver 532 of memory die 522-5. Alternatively, data can be driven in the opposite direction from transmitter 532 of memory die 522-5 and received by the receiver 532 of memory die 522-1. For example, established data paths are not limited to a particular direction in which data is transmitted and tests may be performed by driving data in any suitable direction through the established data path (e.g., TSV connections). In the foregoing example, the TSV connections may be tested for memory die 522-1 and memory die 522-5. In some embodiments, intermediate memory die (e.g., 522-2, 522-3, 522-4) may remain inactive. Further, on the second data path, data may be driven through TSV 524-2 from transmitter 532 of memory die 522-2 and received by the receiver 532 of memory die 522-6. In this example, the TSV connections (e.g., the second data path) may be tested for memory die 522-2 and 522-6. In some embodiments, intermediate memory die (e.g., 522-3, 522-4, 522-5) may remain inactive.

Continuing with the example above, when data is driven through TSVs 524-1 and 524-2, memory dies 522-1, 522-5, 522-2, and 522-6 may be tested. If the stack height includes a total of six DRAM dies, this results in 50% testing coverage of the TSV connections 524. If the stack height is further increased by two DRAM dies for a total stack height of eight DRAM dies, then 100% testing coverage of TSV connections 524 may be accomplished.

For example, on the third data path, data may be driven through TSV 524-3 from transmitter 532 of memory die 522-3 and received by the receiver 532 of memory die 522-7. In this example, the TSV connections may be tested for memory die 522-3 and memory die 522-7. In some embodiments, intermediate memory die (e.g., 522-4, 522-5, 522-6) may remain inactive. Further, on the fourth data path, data may be driven through TSV 524-4 from transmitter 532 of memory die 522-4 and received by the receiver 532 of memory die 522-8. In this example, the TSV connections may be tested for memory die 522-4 and 522-8. In some embodiments, intermediate memory die (e.g., 522-5, 522-6, 522-7) may remain inactive.

Testing TSVs 524-1, …, 524-4 (on which four data paths are established as shown in FIG. 5) may be performed simultaneously. Alternatively speaking, the (e.g., four) data paths established among the TSVs 524-1, .., 524-4 can be tested simultaneously. Additionally, testing TSVs 524-1, …, 524-4 may be performed independently of each other. In this way, the rate of TSV testing may be increased compared to previous methods. Testing each TSV may be performed and managed by an external device.

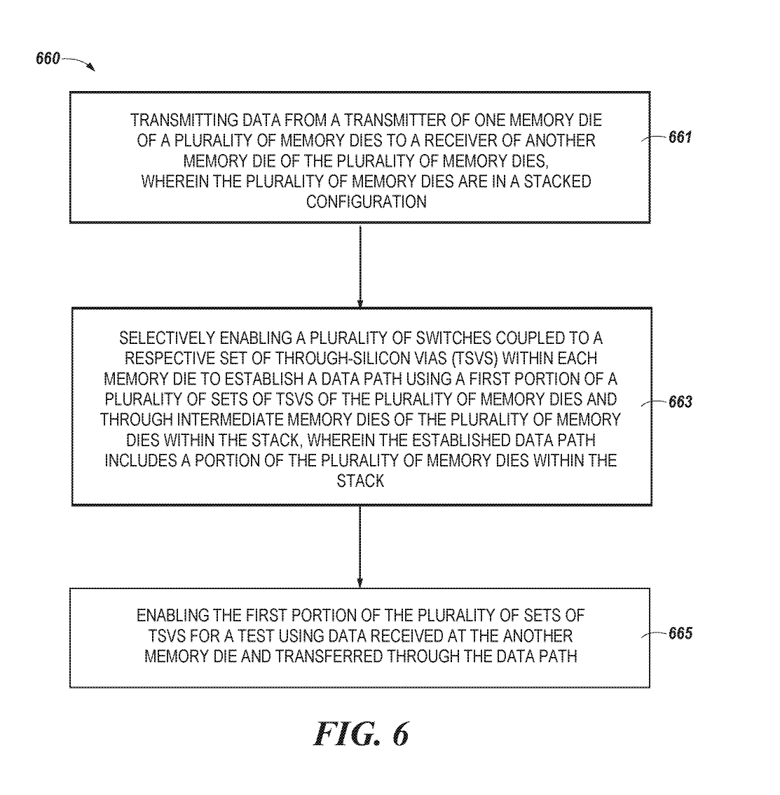

FIG. 6 illustrates a method of testing through-silicon via connections in memory devices in accordance with a number of embodiments of the present disclosure. The method 660 may be performed by memory device 206 as described in connection with FIG. 2, for example. Portions of the method 660 may also be performed by components of the apparatuses illustrated in FIG. 3-5, for example.

At block 661, the method includes transmitting data from a transmitter of one memory die of a plurality of memory dies to a receiver of another memory die of the plurality of memory dies, wherein the plurality of memory dies are in a stacked configuration. For example, data may be transmitted from transmitter 432 of memory die 422-1 of FIG. 4. Transmitting the data from the transmitter of the one memory die to the receiver of another memory die may be initiated by a testmode control logic unit as part of enabling a plurality of TSVs for a test. For example, enabling a plurality of TSVs for a test may be initiated by testmode control logic 430 of memory die 422-1 illustrated in FIG. 4. The plurality of TSVs may be enabled for a test before the memory dies have been stacked to a final stack height.

At block 663, the method includes selectively enabling a plurality of switches coupled to a respective set of through-silicon vias (TSVs) within each memory die to establish a data path using a first portion of a plurality of sets of TSVs of the plurality of memory dies and through intermediate memory dies of the plurality of memory dies within the stack, wherein the established data path includes a portion of the plurality of memory dies within the stack. For example, a plurality of switches may be enabled in memory die 422-4 to alter a data path through memory die 422-2 and memory die 422-3. Enabling the plurality of switches to later the data path may include bypassing some of the plurality of TSVs within each memory die such that the data is transmitted through a different TSV of each memory die.

At block 665, the method includes enabling the first portion of the plurality of sets of TSVs for a test using data received at another memory die and transferred through the data path. The method 600 may also include receiving the data at the receiver of another memory die. For example, the data may be received by receiver 432 of memory die 422-4 or receiver 432 of memory die 422-3 illustrated in FIG. 4. The method may further include reading out the received data using a probe pad coupled to the memory dies. For example, the received data may be read out using probe pad 426 coupled to memory die 422-4 or probe pad 426 coupled to memory die 422-3.

The method 600 may include determining a failure event has occurred within at least one of the plurality of TSVs by comparing the received data to an expected data. The failure event may include detecting a short or an open within the data path. For example, by altering the data path through the enabling of a combination of switches between the TSVs, a failure event may be detected at a particular point within the data path. The failure event may be detected by comparing the received data to the transmitted data, for example. External testing circuitry, such as external device 110 of FIG. 1, may determine the presence of a failure event among the TSVs.

The method 660 may further include transmitting further data from the transmitter of a different memory die. For example, further data may be transmitted from transmitter 432 of memory die 422-3 of FIG. 4. The method 660 may also include enabling a different plurality of switches such that the further data follows a different data path. Further, method 660 may include receiving the further data by the receiver of another memory die. For example, the further data may be received by receiver 432 of memory die 422-4 of FIG. 4.

Method 660 may also include testing the plurality of TSVs in intermediate stacks of four memory dies. As an example, testing the plurality of TSVs may be performed in stacks of four memory dice at a time, but embodiments are not limited as such.

Further, method 660 may include determining the at least one of the plurality of TSVs is experiencing the failure event. For example, an external device may determine which TSV is experiencing the event by locating the failure event within the data path.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
transmitting data from a transmitter of one memory die of a plurality of memory dies to a receiver of another memory die of the plurality of memory dies, wherein the plurality of memory dies are in a stacked configuration;
selectively enabling a plurality of switches coupled to a respective set of through-silicon vias (TSVs) within each memory die to establish a data path using a first portion of a plurality of sets of TSVs of the plurality of memory dies and through intermediate memory dies of the plurality of memory dies within the stack, wherein the established data path includes a portion of the plurality of memory dies within the stack; and
enabling the first portion of the plurality of sets of TSVs for a test using data received at the another memory die and transferred through the data path.

2. The method of claim 1, wherein transmitting the data from the transmitter of the one memory die to the receiver of the another memory die is initiated by a test mode control logic unit as part of enabling the first portion of the plurality of sets of TSVs for a test.

3. The method of claim 2, wherein the test of the first portion of the plurality of sets of TSVs is enabled before the plurality of memory dies have been stacked to a final stack height.

4. The method of claim 1, wherein the method includes determining a failure event has occurred within at least one TSV among the first portion of the plurality of sets of TSVs.

5. The method of claim 4, wherein determining the failure event has occurred within the at least one TSV among the first portion of the plurality of sets of TSVs includes comparing received data at the another memory die to an expected data.

6. The method of claim 1, wherein selectively enabling the plurality of switches to establish the data path includes bypassing some of the plurality of TSVs within each memory die such that the data is transmitted through a different portion of the plurality of sets of TSVs of the plurality of memory dies.

7. The method of claim 1, further comprising:
transmitting further data from the transmitter of a different memory die;
enabling a different plurality of switches such that the further data follows a different data path; and
receiving the further data by the receiver of the another memory die.

8. The method of claim 1, wherein the first portion of the plurality of sets of TSVs includes four memory dies.

9. A memory device, comprising:
a plurality of memory dies in a stacked configuration, wherein each memory die within the stack comprises:
a plurality of sets of through-silicon vias (TSVs) configured to transfer data from one memory die to another memory die;
a test mode control logic unit configured to initiate a test of a respective set of the plurality of sets of TSVs by transferring the data from a transmitter of the one memory die to a receiver of the another memory die;
a plurality of switches coupled to the respective set of the plurality of sets of TSVs and configured to establish a data path using a first portion of the plurality of sets of TSVs; and
a probe pad configured to provide the transferred data to an external test circuit to determine if the test was successful.

10. The memory device of claim 9, wherein the test is determined to be successful when the transferred data received by the another memory die matches the data transmitted from the one memory die.

11. The memory device of claim 9, wherein the test is enabled before a base die is connected to the plurality of memory dies.

12. The memory device of claim 9, wherein the plurality of memory dies in the stacked configuration comprise Dynamic Random-Access Memory configured to form a High Bandwidth Memory (HBM) cube.

13. The memory device of claim 9, wherein the transmitter and the receiver are coupled to one of the plurality of sets of TSVs on each memory die.

14. The memory device of claim 9, wherein a different combination of the plurality of switches are enabled for each test enabled.

15. The memory device of claim 9, wherein the plurality of memory dies in the stacked configuration includes at least two memory die.

16. An apparatus, comprising:
a plurality of memory dies configured in a stack formation;
a plurality sets of through-silicon vias (TSVs) configured to provide a communication pathway between the plurality of memory dies;
a plurality of switches coupled to the plurality of sets of TSVs and configured to control the communication pathway between the plurality of memory dies when activated by a test mode control logic unit; and
a probe pad configured to provide data transmitted through the communication pathway to an external test circuit, wherein the external test circuit is configured to:
compare the transmitted data to an expected data; and
determine whether the plurality of TSVs pass a test based on the comparison.

17. The apparatus of claim 16, wherein the test includes altering the communication pathway by enabling a combination of the plurality of switches such that the data passes through a different set of the plurality of sets of TSVs within each memory die among the plurality of memory dies.

18. The apparatus of claim 16, wherein the plurality of sets of TSVs are four-spiral TSVs.

19. The apparatus of claim 16, wherein the plurality of switches are enabled such that multiple communication pathways are established in parallel through the plurality of memory dies in the stack formation.

20. The apparatus of claim 19, wherein the multiple communication pathways are configured such that the data is transmitted through each TSV among the plurality of sets of TSVs on each memory die in parallel.
